(19) United States
(12) Patent Application Publication
(10) Pub. No.: US 2025/0380485 A1
(43) Pub. Date: Dec. 11, 2025

(54) SEMICONDUCTOR DEVICE

(71) Applicant: ROHM CO., LTD., Kyoto (JP)

(72) Inventor: Yuji MATSUMOTO, Kyoto (JP)

(73) Assignee: ROHM CO., LTD., Kyoto (JP)

(21) Appl. No.: 19/223,838

(22) Filed: May 30, 2025

(30) Foreign Application Priority Data
Jun. 5, 2024 (JP) 2024-091420

(51) Int. Cl. H10D 64/27; H10D 30/65

(52) U.S. Cl. CPC H10D 64/518; H10D 30/65; H10D 64/519

(57) ABSTRACT

A semiconductor device includes a source region extending along a Y axis direction, a first drain region, a first gate electrode disposed between the source region and the first drain region, a second drain region positioned across the source region from the first drain region, and extending along the Y axis direction, and a second gate electrode disposed between the source region and the second drain region. The first gate electrode extends in a meander along the Y axis direction, and the second gate electrode extends in a meander along the Y axis direction. In the source region disposed between the first gate electrode and the second gate electrode, a conductive region having a conductivity type opposite to the source region is formed, and the source region and the conductive region are electrically connected to each other.

### CROSS REFERENCE TO RELATED APPLICATION

This application is based upon and claims the benefit of priority of the prior Japanese Patent Application No. 2024-091420, filed on Jun. 5, 2024, the entire contents of which are incorporated herein by reference.

### Technical Field

The present disclosure relates to a semiconductor device.

### Background Art

WO 2022/153693 discloses a semiconductor device including a field effect transistor.

### BRIEF DESCRIPTION OF THE DRAWINGS

FIG. 1 is a plan view of a semiconductor chip.

FIG. 2 is a plan view of a device region.

FIG. 3 is a diagram showing a vertical cross-sectional configuration along the arrow A-A of the device region shown in FIG. 2.

FIG. 4 is a diagram showing a vertical cross-sectional configuration along the arrow B-B of the device region shown in FIG. 2.

FIG. 5 is a circuit diagram of a transistor group connected in parallel.

FIG. 6 is a plan view of a device region.

FIG. 7 is a diagram showing a vertical cross-sectional configuration along the arrow A-A of the device region shown in FIG. 6.

FIG. 8 is a diagram showing a vertical cross-sectional configuration along the arrow B-B of the device region shown in FIG. 6.

FIG. 9 is a circuit diagram of a transistor group connected in parallel.

FIG. 10 is a plan view of a transistor.

FIG. 11 is a plan view of a semiconductor chip including a BCD circuit.

### DETAILED DESCRIPTION OF EMBODIMENTS

Below, various exemplary embodiments will be described in detail with reference to the drawings. The same or corresponding components in the drawings are assigned the same reference characters and redundant explanations thereof will be omitted.

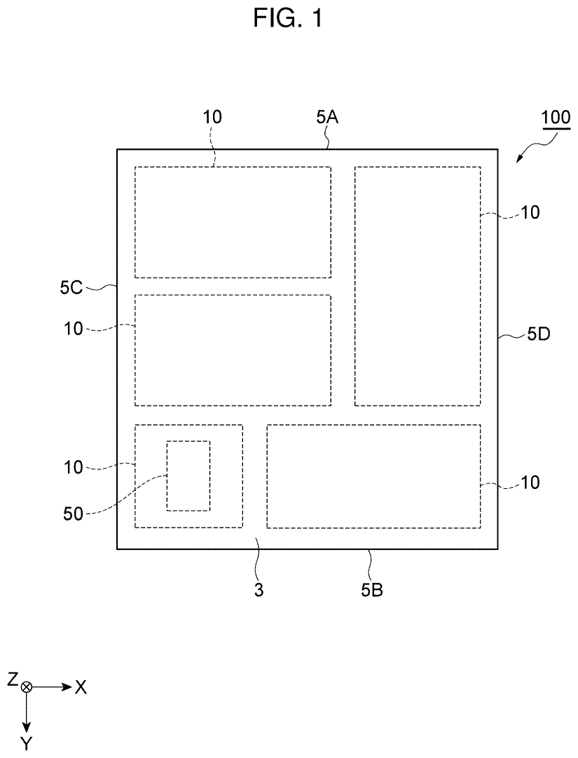

FIG. 1 is a plan view of a semiconductor chip.

A semiconductor chip 100 (semiconductor device) has a rectangular cuboid shape. The semiconductor chip 100 has a first main surface 3 on one side. A rear surface is positioned on the side opposite to the first main surface 3. The semiconductor chip 100 has a first side face 5A, a second side face 5B, a third side face 5C, and a fourth side face 5D that connect the first main surface 3 and the rear surface. The thickness direction of the semiconductor chip 100 is designated as the Z axis direction, a direction orthogonal to the Z axis is designated as the X axis direction, and the direction orthogonal to both the Z axis and the X axis is designated as the Y axis direction. Furthermore, the depth direction of the semiconductor chip 100 is designated as the positive direction along the Z axis, and the negative direction along the Z axis indicates the direction from the rear surface towards the first main surface 3 (top surface) of the semiconductor substrate. Where an XYZ three-dimensional orthogonal coordinate system in which the depth direction is the Z axis direction is set, FIG. 1 is a plan view as seen from the Z axis direction.

The first main surface 3 and the rear surface are perpendicular to the Z axis. The planar shape (plan view shape) of the first main surface 3 as seen from the normal line direction (Z axis direction) of the first main surface 3 is rectangular (quadrilateral). The plan view shape of the rear surface of the semiconductor substrate is rectangular (quadrilateral). The first side face 5A and the second side face 5B constituting two opposing sides of the rectangle in a plan view both extend along the X axis direction. The third side face 5C and the fourth side face 5D constituting two other opposing sides of the rectangle in a plan view both extend along the Y axis direction. These adjacent side faces are perpendicular to each other in a plan view, but can alternatively intersect at a non-right angle.

The semiconductor chip 100 includes a plurality of device regions 10 provided on the first main surface 3. A gap is provided between each device region 10 and each side face (first side face 5A to fourth side face 5D) of the semiconductor chip 100. The number, arrangement, and shape of the device regions 10 is not limited to any specific number, arrangement or shape.

Various devices are formed in each of the device regions 10. In this example, at least one device region 10 includes a device 50.

An example of the device 50 is a field effect transistor. Field effect transistors can also be used as power transistors. An example of the type of transistor used for the field effect transistor of this example is a metal-insulator-semiconductor field effect transistor (MISFET). A metal-oxide-semiconductor field effect transistor (MOSFET) can be used as the MISFET. The MOSFET of the present embodiment is an extended drain (ED) MOSFET. A typical EDMOSFET includes an N-type well region where N-type carriers drift towards the drain region. Examples of a drain-source voltage of the MISFET include high voltage HV (e.g., 100V to 1,000V, inclusive), middle voltage MV (e.g., 30V to 100V, inclusive), and low voltage LV (e.g., 1V to 30V, inclusive).

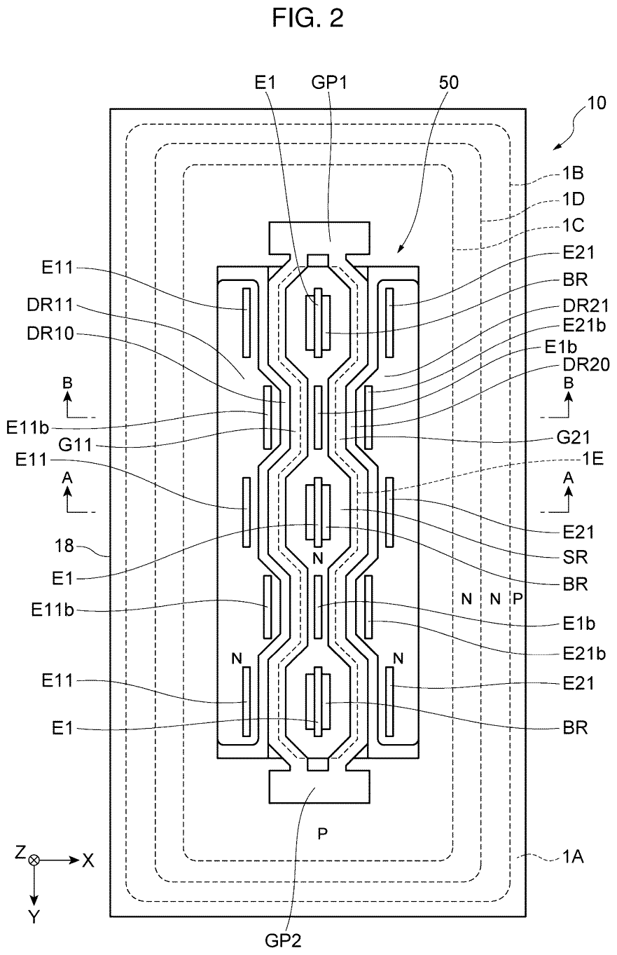

FIG. 2 is a plan view of the device region.

The device 50 is formed in the central portion of the device region 10. The device 50 is a field effect transistor (FET). Surface contact layers are positioned on the surfaces of the source region and the drain region of the device 50, but are not shown in the drawing. The surface surrounding the device 50 in the device region 10 is covered by an insulating region 18. The insulating region 18 is a field oxide film, a shallow trench isolation (STI) element, or the like. In each semiconductor region, the P type is designated as a first conductivity type and the N type is designated as a second conductivity type, but the conductivity types can alternatively be interchanged with each other.

In a plan view in the Z axis direction, the device 50 includes a source region SR, a first drain region DR11, a first gate electrode G11, a second drain region DR21, and a second gate electrode G21. The source region SR extends in the Y axis direction. The first drain region DR11 extends in the Y axis direction. The first gate electrode G11 is disposed between the source region SR and the first drain region DR11. The second drain region DR21 is positioned across the source region SR from the first drain region DR11, and extends in the Y axis direction. The second gate electrode G21 is disposed between the source region SR and the second drain region DR21. A P-type semiconductor layer 1E extending along the Y axis direction is present below the source region SR.

The first gate electrode G11 extends in a meander along the Y axis direction. The second gate electrode G21 extends in a meander along the Y axis direction. In the source region SR disposed between the first gate electrode G11 and the second gate electrode G21, conductive regions BR (P-type butting region) of the opposite conductivity type to the source region SR are formed. The conductive regions BR are disposed periodically in the Y axis direction. Thus, the source region SR and the conductive regions BR are periodically electrically connected to each other along the Y axis direction. The conductive regions BR are disposed in regions with a wide gap in the X axis direction between the first gate electrode G11 and the second gate electrode G21, and are not disposed in narrow gap regions.

The conductive regions BR are connected to a back gate of the field effect transistor. In a power transistor, a back gate is used in order to prevent operation of a parasitic transistor of the field effect transistor. If the gate electrode is simply provided in a linear fashion, the effective channel width is reduced, which increases the gate capacitance. As a measure to suppress ON-resistance and an increase in gate capacitance, one possible structure is one in which the conductive region extends in the Y axis direction, but this would increase the distance between drain regions (cell pitch) in the left-right direction, thereby increasing the ON-resistance. Another possible method is one in which the width of the source region is reduced, but this reduces manufacturing stability. If the width of the N-type source region or drain region is excessively reduced, this results in the P-type conductive region BR affecting transistor characteristics.

Thus, the first gate electrode G11 and the second gate electrode G21 are provided in a meandering (wave-like) shape, and furthermore, the conductive region BR is selectively disposed in a region of the source region SR with a relatively wide gap between the gate electrodes, and the conductive region BR is not disposed in a region with a relatively narrow gap between the gate electrodes. By forming the first gate electrode G11 and the second gate electrode G21 in a wave-like shape, it is possible to increase the gate width per unit area while preventing an increase in pitch. The conductive region BR is disposed in an isolated island shape, and allows for mitigating a decrease in gate width and an increase in gate capacitance, reducing the ON-resistance, and increasing the switching efficiency.

A first electrode unit GP1 is disposed on the negative direction end in the Y axis direction. A second electrode unit GP2 is disposed on the positive direction end in the Y axis direction. The first gate electrode G11 connects the first electrode unit GP1 to the second electrode unit GP2. Similarly, the second gate electrode G21 connects the first electrode unit GP1 to the second electrode unit GP2.

A portion of a first lower drain region DR10, to which a middle voltage is applied, is positioned between the first drain region DR11 and the source region SR, and the first lower drain region DR10 is also positioned below the first drain region DR11 in the depth direction. In the first row of transistors closer to the first electrode unit GP1, a first drain electrode E11 is disposed on the first drain region DR11. Similarly, in odd-numbered ((2N−1)th rows) rows of transistors, the first drain electrode E11 is disposed on the first drain region DR11 (N being a natural number). Meanwhile, in even-numbered ((2N)th rows) rows of transistors, a first drain electrode E11b in an even-numbered row is disposed on the first drain region DR11.

The first drain electrodes E11 in odd-numbered rows are disposed at positions farther from the source electrodes E1 (E1b) than the first drain electrodes E11b in even-numbered rows.

A portion of a second lower drain region DR20, to which a middle voltage is applied, is positioned between the second drain region DR21 and the source region SR, and the second lower drain region DR20 is also positioned below the second drain region DR21 in the depth direction. In the first row of transistors closer to the first electrode unit GP1, a second drain electrode E21 is disposed on the second drain region DR21. Similarly, in odd-numbered ((2N−1)th rows) rows of transistors, the second drain electrode E21 is disposed on the second drain region DR21 (N being a natural number). Meanwhile, in even-numbered ((2N)th rows) rows of transistors, a second drain electrode E21b in an even-numbered row is disposed on the second drain region DR21.

The second drain electrodes E21 in odd-numbered rows are disposed at positions farther from the source electrodes E1 (E1b) than the drain electrodes E21b in even-numbered rows.

The conductive regions BR (semiconductor region) are disposed in odd-numbered row sections of the source region SR. The conductive regions BR are not disposed in even-numbered row sections of the source region SR. In odd-numbered rows of transistors, the source electrode E1 is disposed on the source region SR, and the source electrode E1 is also connected to the conductive region BR. Similarly, in even-numbered rows of transistors, the source electrode E1b is disposed on the source region SR.

Source electrodes E1 in odd-numbered rows are formed on the conductive region BR, whereas no conductive region BR is present under source electrodes E1b in even-numbered rows.

In this example, the conductivity type of the source region SR, the first drain region DR11, the first lower drain region DR10, the second drain region DR21, and the second lower drain region DR20 is the N type. The conductivity type of the P-type semiconductor layer 1E and the conductive region BR is the P type. FETs included in such semiconductor regions are formed in a P-type well region 1C. The P-type well region 1C is formed in a second N-type semiconductor layer 1D. The second N-type semiconductor layer 1D can form a PN junction with the P-type well region 1C. A first N-type well region 1B is formed in a surface region of a semiconductor substrate 1A.

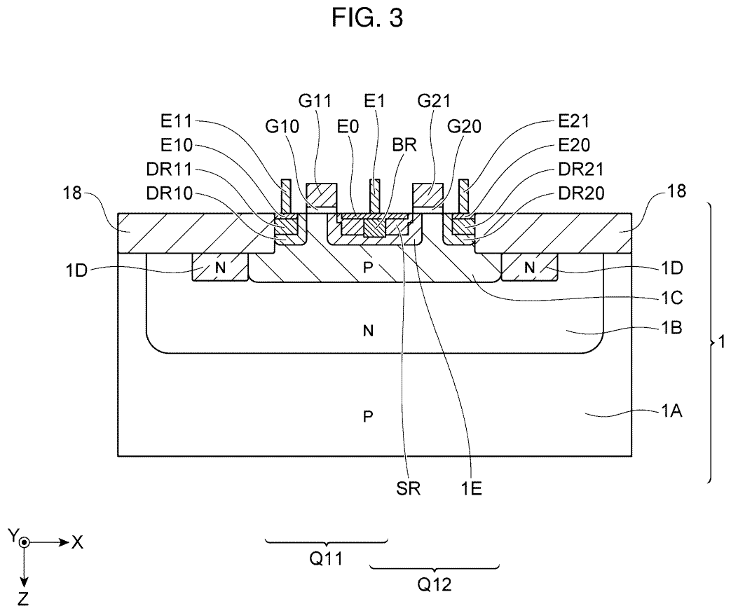

FIG. 3 is a diagram showing a vertical cross-sectional configuration along the arrow A-A of the device region shown in FIG. 2.

FIG. 3 shows a cross-section of a transistor in an odd-numbered row (e.g., third row) from the first electrode unit GP1. In a substrate 1, the first N-type well region 1B is formed on the semiconductor substrate 1A, and the P-type well region 1C is formed on the first N-type well region 1B. The P-type well region 1C is surrounded by the second N-type semiconductor layer 1D in a plan view. The impurity concentration of the second N-type semiconductor layer 1D can be set higher than the impurity concentration of the first N-type well region 1B. The source region SR, the first lower drain region DR10, the second lower drain region DR20, and the P-type semiconductor layer 1E are formed in the P-type well region 1C. The first drain region DR11 is formed on the first lower drain region DR10. The second drain region DR21 is formed on the second lower drain region DR20. The source region SR and the conductive region BR are formed in the P-type semiconductor layer 1E. The conductive region BR is connected to the P-type semiconductor layer 1E. The first lower drain region DR10 and the second lower drain region DR20 contribute to an increase in hot carrier durability.

A first surface contact layer E10 is formed on the first drain region DR11. A second surface contact layer E20 is formed on the second drain region DR21. A surface contact layer E0 is formed on the source region SR and the conductive region BR. The surface contact layer E0 is electrically connected to the source region SR and the conductive region BR. The first surface contact layer E10, the second surface contact layer E20, and the surface contact layer E are made of a conductive material. Examples of such a conductive material include an impurity-doped polysilicon, a metal (aluminum, etc.), or a silicide (tungsten silicide, titanium silicide, cobalt silicide, nickel silicide, etc.).

The first drain electrode E11 is formed on the first surface contact layer E10. The second drain electrode E21 is formed on the second surface contact layer E20. The source electrode E1 is formed on the surface contact layer E0.

The first gate electrode G11 is formed, via a first gate insulating film G10, over a region between the first drain region DR11 and the source region SR. The second gate electrode G21 is formed, via a second gate insulating film G20, over a region between the second drain region DR21 and the source region SR.

A first transistor Q11 includes the first drain region DR11 and the source region SR. A second transistor Q12 includes the second drain region DR21 and the source region SR. That is, the source region SR is common to the first transistor Q11 and the second transistor Q12.

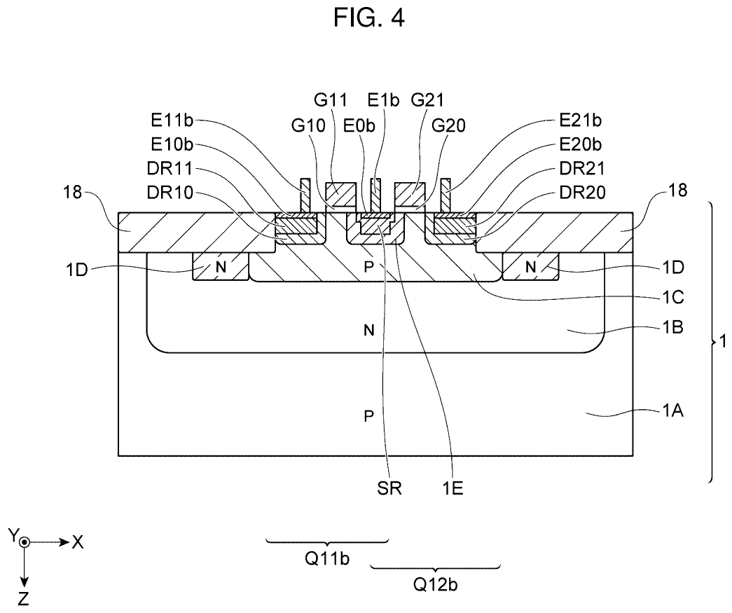

FIG. 4 is a diagram showing a vertical cross-sectional configuration along the arrow B-B of the device region shown in FIG. 2.

FIG. 4 shows a cross-section of a transistor in an even-numbered row (e.g., second row) from the first electrode unit GP1. The difference from the cross-sectional view of FIG. 3 is that the conductive region BR is not formed in the source region SR of FIG. 4, and thus, the X axis direction width of the source region SR is narrower. With the reduced X axis direction width of the source region SR, the X axis direction widths of the first lower drain region DR10, the second lower drain region DR20, the first drain region DR11, and the second drain region DR21 are increased. The configuration is otherwise the same as that of the device region shown in FIG. 3.

A first surface contact layer E10b is formed on the first drain region DR11. A second surface contact layer E20b is formed on the second drain region DR21. A surface contact layer E0b is formed on the source region SR. The first surface contact layer E10b, the second surface contact layer E20b, and the surface contact layer E0b are made of a conductive material. Examples of such a conductive material include an impurity-doped polysilicon, a metal (aluminum, etc.), or a silicide (tungsten silicide, titanium silicide, cobalt silicide, nickel silicide, etc.).

The first drain electrode E11b is formed on the first surface contact layer E10b. The second drain electrode E21b is formed on the second surface contact layer E20b. The source electrode E1b is formed on the surface contact layer E0b.

A first transistor Q11b includes the first drain region DR11 and the source region SR. A second transistor Q12b includes the second drain region DR21 and the source region SR. That is, the source region SR is common to the first transistor Q11b and the second transistor Q12b.

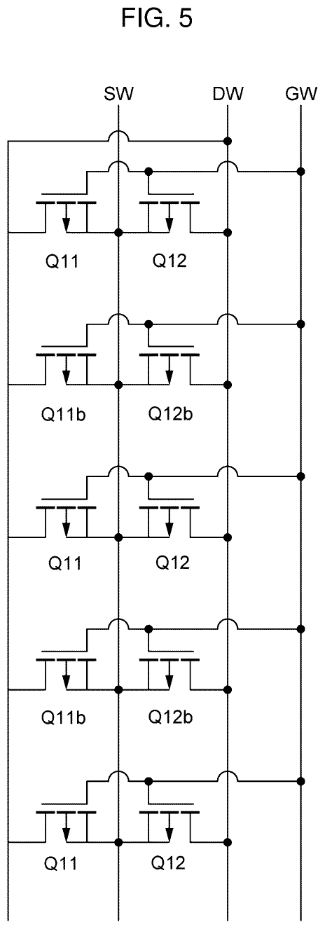

FIG. 5 is a circuit diagram of a transistor group connected in parallel.

Each field effect transistor shown in FIG. 5 is an NMOS (N-channel MOS) FET.

The gate electrodes of all of the transistors (first transistor Q11 in odd-numbered row, first transistor Q11b in even-numbered row, second transistor Q12 in odd-numbered row, second transistor Q12b in even-numbered row) are electrically connected to a gate electrode wiring line GW. Similarly, the source electrodes of all of the transistors are electrically connected to a source electrode wiring line SW. Additionally, the drain electrodes of all of the transistors are electrically connected to a drain electrode wiring line DW. The transistor group is connected in parallel and can function as a high-withstand-voltage transistor.

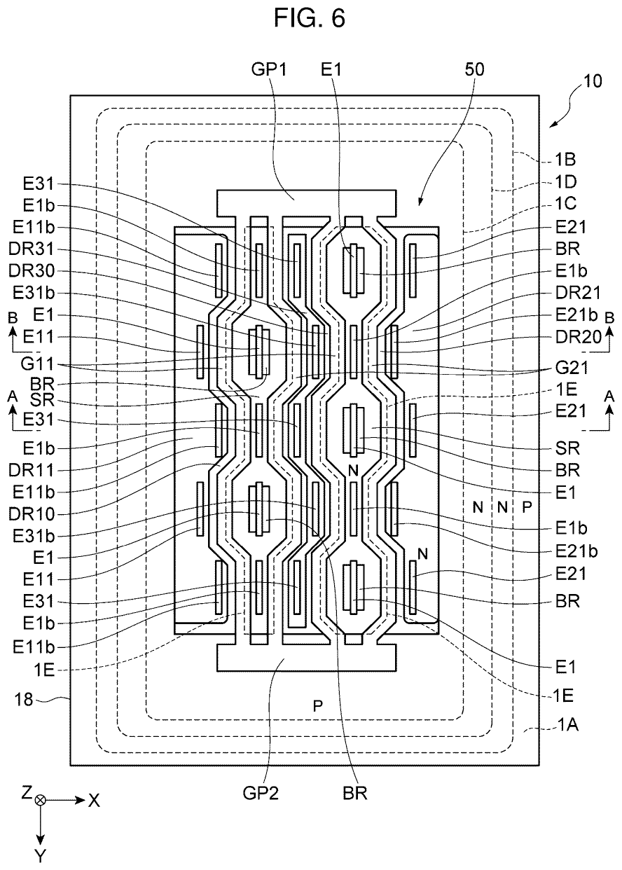

FIG. 6 is a plan view of the device region including a plurality of columns of source regions.

The device 50 is formed in the central portion of the device region 10. The device 50 is a field effect transistor (FET). Surface contact layers are positioned on the surfaces of the source region and the drain region of the device 50, but are not shown in the drawing. The surface surrounding the device 50 in the device region 10 is covered by an insulating region 18. The insulating region 18 is a field oxide film, an STI element, or the like.

The device 50 includes two columns (plurality of columns) of source regions SR in a plan view as seen from the Z axis direction.

The right-side region of the device 50 has the same basic structure as that shown in FIG. 2, and shares a drain region with the left-side region. That is, the right-side region of the device 50 includes a common drain region DR31, the first gate electrode G11, the source region SR, the second gate electrode G21, and the second drain region DR21. The source region SR in the right column extends in the Y axis direction. The common drain region DR31 extends in the Y axis direction. The first gate electrode G11 in the right column is disposed between the source region SR and the common drain region DR31. The second drain region DR21 is positioned across the source region SR in the right column from the common drain region DR31, and extends in the Y axis direction. The second gate electrode G21 in the right column is disposed between the source region SR and the second drain region DR21. A P-type semiconductor layer 1E extending along the Y axis direction is present below the source region SR in the right column.

The left-side region of the device 50 has a structure that is shifted from the right-side region by a half period of the gate electrode, which meanders in a periodic fashion in the right-side region. That is, the left-side region of the device 50 includes the first drain region DR11, the first gate electrode G11, the source region SR, the second gate electrode G21, and the common drain region DR31. The source region SR in the left column extends in the Y axis direction. The first drain region DR11 is positioned across the source region SR in the left column from the common drain region DR31, and extends in the Y axis direction. The first gate electrode G11 in the left column is disposed between the first drain region DR11 and the source region SR. The second gate electrode G21 in the left column is disposed between the source region SR and the common drain region DR31. A P-type semiconductor layer 1E extending along the Y axis direction is present below the source region SR in the left column.

The first gate electrodes G11 in the right column and the left column extend in a meander along the Y axis direction. The second gate electrodes G21 in the right column and the left column extend in a meander along the Y axis direction. In the source region SR disposed between the first gate electrode G11 and the second gate electrode G21, conductive regions BR (P-type butting region) of the opposite conductivity type to the source region SR are formed. The conductive regions BR are disposed periodically in the Y axis direction. Thus, the source region SR and the conductive regions BR are periodically electrically connected to each other along the Y axis direction. The conductive regions BR are disposed in regions with a wide gap in the X axis direction between the first gate electrode G11 and the second gate electrode G21, and are not disposed in narrow gap regions.

A first electrode unit GP1 is disposed on the negative direction end in the Y axis direction. A second electrode unit GP2 is disposed on the positive direction end in the Y axis direction. The first gate electrodes G11 in the right column and the left column connect the first electrode unit GP1 to the second electrode unit GP2. Similarly, the second gate electrodes G21 in the right column and the left column connect the first electrode unit GP1 to the second electrode unit GP2.

A portion of a first lower drain region DR10, to which a middle voltage is applied, is positioned between the first drain region DR11 and the source region SR in the left column, and the first lower drain region DR10 is also positioned below the first drain region DR11 in the depth direction. A portion of a second lower drain region DR20, to which a middle voltage is applied, is positioned between the second drain region DR21 and the source region SR in the right column, and the second lower drain region DR20 is also positioned below the second drain region DR21 in the depth direction. A portion of a common lower drain region DR30, to which a middle voltage is applied, is positioned between the common drain region DR31 and the left and right source regions SR, and the common lower drain region DR30 is also positioned below the common drain region DR31 in the depth direction.

In odd-numbered ((2N−1)th rows) rows of transistors as counted from the first electrode unit GP1, the drain electrodes and the source electrodes are arranged as follows (N being a natural number). The first drain electrodes E11b are disposed on the first drain region DR11. The source electrodes E1b are disposed on the source region SR in the left column. Common drain electrodes E31 are disposed on the common drain region DR31. The source electrodes E1 are disposed on the source region SR and the conductive regions BR in the right column. The second drain electrodes E21 are disposed on the second drain region DR21.

In even-numbered ((2N)th rows) rows of transistors as counted from the first electrode unit GP1, the drain electrodes and the source electrodes are arranged as follows (N being a natural number). The first drain electrodes E11 are disposed on the first drain region DR11. The source electrodes E1 are disposed on the source region SR and the conductive regions BR in the left column. Common drain electrodes E31b are disposed on the common drain region DR31. The source electrodes E1b are disposed on the source region SR in the right column. The second drain electrodes E21b are disposed on the second drain region DR21.

The first drain electrodes E11b in odd-numbered rows are disposed at positions closer to the source electrodes E1b (E1) in the left column than the first drain electrodes E11 in even-numbered rows. The second drain electrodes E21 in odd-numbered rows are disposed at positions farther from the source electrodes E1 (E1b) in the right column than the second drain electrodes E21b in even-numbered rows. The common drain electrodes E31 in odd-numbered rows are disposed at positions farther from the source electrodes E1 (E1b) in the right column than the common drain electrodes E31b in even-numbered rows.

The conductive regions BR are disposed in odd-numbered row sections of the source region SR in the right column, and the conductive regions BR are not disposed in even-numbered row sections of the source region SR in the right column. The conductive regions BR are not disposed in odd-numbered row sections of the source region SR in the left column, and the conductive regions BR are disposed in even-numbered row sections of the source region SR in the left column.

The source electrodes E1b are disposed in odd-numbered row sections of the source region SR in the left column, the source electrodes E1 are disposed on the source region SR in the right column, and the source electrodes E1 are also connected to the conductive regions BR. The source electrodes E1 are disposed in even-numbered row sections of the source region SR in the left column, the source electrodes E1 are also connected to the conductive regions BR, and the source electrodes E1b are also disposed on the source region SR in the right column. The source electrodes E1 are formed on the conductive regions BR, whereas no conductive region BR is present under the source electrodes E1b.

In this example, the conductivity type of the source regions SR, the first drain region DR11, the first lower drain region DR10, the second drain region DR21, the second lower drain region D20, the common drain region DR31, and the common lower drain region DR30 is the N type. The conductivity type of the P-type semiconductor layer 1E and the conductive region BR is the P type. FETs included in such semiconductor regions are formed in a P-type well region 1C. The P-type well region 1C is formed in a second N-type semiconductor layer 1D. The second N-type semiconductor layer 1D is formed in the first N-type well region 1B. A first N-type well region 1B is formed in a surface region of a semiconductor substrate 1A.

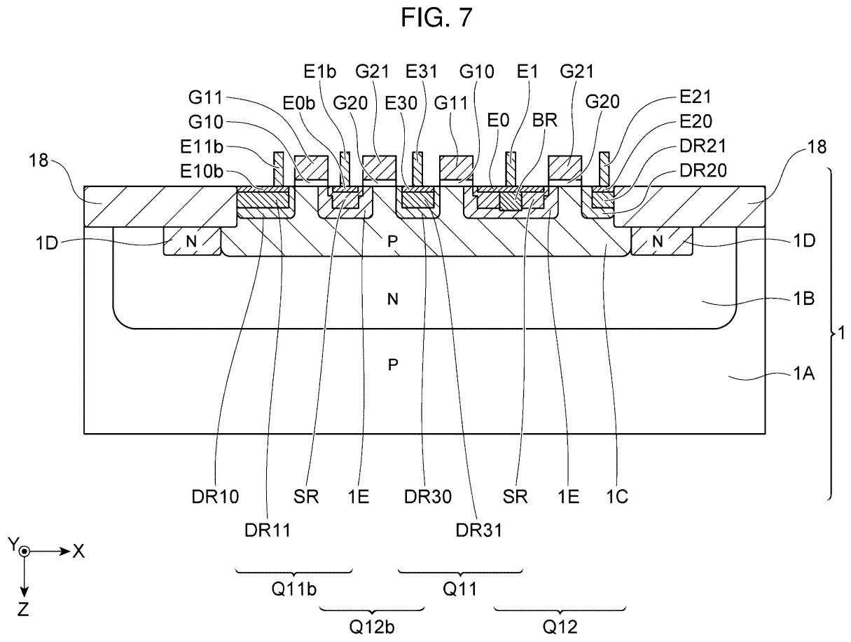

FIG. 7 is a diagram showing a vertical cross-sectional configuration along the arrow A-A of the device region shown in FIG. 6.

FIG. 7 shows a cross-section of a transistor in an odd-numbered row (e.g., third row) from the first electrode unit GP1. In a substrate 1, the first N-type well region 1B is formed on the semiconductor substrate 1A, and the P-type well region 1C is formed on the first N-type well region 1B. The P-type well region 1C is surrounded by the second N-type semiconductor layer 1D in a plan view. The impurity concentration of the second N-type semiconductor layer 1D can be set higher than the impurity concentration of the first N-type well region 1B.

The first lower drain region DR10, the left-side P-type semiconductor layer 1E, the common lower drain region DR30, the right-side P-type semiconductor layer 1E, and the second lower drain region DR20 are formed in the P-type well region 1C.

The first drain region DR11 is formed on the first lower drain region DR10. A first surface contact layer E10b is formed on the first drain region DR11. The first drain electrode E11b is formed on the first surface contact layer E10b.

The left-side source region SR is formed on the left-side P-type semiconductor layer 1E. A surface contact layer E0b is formed on the left-side source region SR. The source electrode E1b is formed on the surface contact layer E0b.

The common drain region DR31 is formed on the common lower drain region DR30. A common surface contact layer E30 is formed on the common drain region DR31. The common drain electrode E31 is formed on the common surface contact layer E30.

The source region SR and the conductive region BR on the right side are formed on the right-side P-type semiconductor layer 1E. A surface contact layer E0 is formed on the source region SR and the conductive region BR on the right side. The source electrode E1 is formed on the surface contact layer E0. The surface contact layer E0 is electrically connected to the source region SR and the conductive region BR on the right side. The conductive region BR is connected to the P-type semiconductor layer 1E.

The second drain region DR21 is formed on the second lower drain region DR20. A second surface contact layer E20 is formed on the second drain region DR21. The second drain electrode E21 is formed on the second surface contact layer E20.

The first surface contact layer (E10b), the second surface contact layer (E20b), the surface contact layers (E0, E0b), and the common surface contact layer E30 are made of a conductive material. Examples of such a conductive material include an impurity-doped polysilicon, a metal (aluminum, etc.), or a silicide (tungsten silicide, titanium silicide, cobalt silicide, nickel silicide, etc.).

The first gate electrode G11 is formed, via a left-side first gate insulating film G10, over a region between the left-side source region SR and the left-side first drain region DR11. The second gate electrode G21 is formed, via a left-side second gate insulating film G20, over a region between the left-side source region SR and the common drain region DR31.

The first gate electrode G11 is formed, via a right-side first gate insulating film G10, over a region between the right-side source region SR and the common drain region DR31. The second gate electrode G21 is formed, via a right-side second gate insulating film G20, over a region between the right-side source region SR and the right-side second drain region DR21.

A left-side first transistor Q11b includes the first drain region DR11 and the left-side source region SR. A left-side second transistor Q12b includes the common drain region DR31 and the left-side source region SR. That is, the left-side source region SR is common to the left-side first transistor Q11b and the second transistor Q12b.

A right-side first transistor Q11 includes the common drain region DR31 and the right-side source region SR. A right-side second transistor Q12 includes the second drain region DR21 and the right-side source region SR. That is, the right-side source region SR is common to the right-side first transistor Q11 and the second transistor Q12.

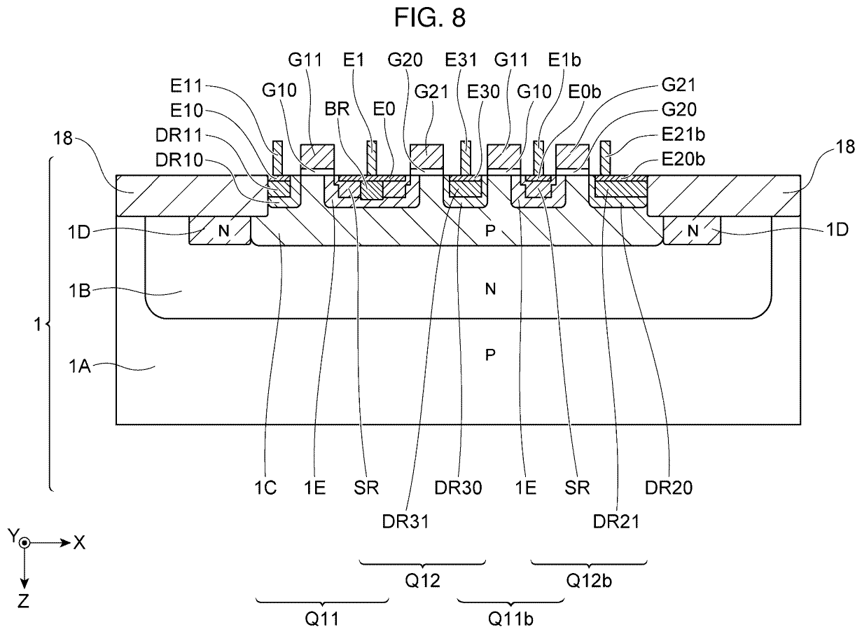

FIG. 8 is a diagram showing a vertical cross-sectional configuration along the arrow B-B of the device region shown in FIG. 6.

FIG. 8 shows a cross-section of a transistor in an even-numbered row (e.g., second row) from the first electrode unit GP1. The cross-section of FIG. 8 has a structure that is left-right inverted, as compared to FIG. 7, about the YZ plane passing through the common drain region DR31 of FIG. 7. The conductive region BR is not formed in the right-side source region SR, and the conductive region BR is formed in the left-side source region SR. Thus, the X axis direction width of the right-side source region SR is reduced, and the X axis direction width of the left-side source region SR is increased. With the reduced X axis direction width of the right-side source region SR, the X axis direction widths of the second lower drain region DR20 and the second drain region DR21 are increased.

The first N-type well region 1B is formed on the semiconductor substrate 1A, and the P-type well region 1C is formed on the first N-type well region 1B. The P-type well region 1C is surrounded by the second N-type semiconductor layer 1D in a plan view. The impurity concentration of the second N-type semiconductor layer 1D can be set higher than the impurity concentration of the first N-type well region 1B.

The first lower drain region DR10, the left-side P-type semiconductor layer 1E, the common lower drain region DR30, the right-side P-type semiconductor layer 1E, and the second lower drain region DR20 are formed in the P-type well region 1C.

The first drain region DR11 is formed on the first lower drain region DR10. A first surface contact layer E10 is formed on the first drain region DR11. The first drain electrode E11 is formed on the first surface contact layer E10.

The source region SR and the conductive region BR on the left side are formed on the left-side P-type semiconductor layer 1E. A surface contact layer E0 is formed on the source region SR and the conductive region BR on the left side. The source electrode E1 is formed on the surface contact layer E0. The surface contact layer E0 is electrically connected to the source region SR and the conductive region BR on the left side. The conductive region BR is connected to the left-side P-type semiconductor layer 1E.

The common drain region DR31 is formed on the common lower drain region DR30. A common surface contact layer E30 is formed on the common drain region DR31. The common drain electrode E31 is formed on the common surface contact layer E30.

The right-side source region SR is formed on the right-side P-type semiconductor layer 1E. A surface contact layer E0b is formed on the right-side source region SR. The source electrode E1b is formed on the surface contact layer E0b.

The second drain region DR21 is formed on the second lower drain region DR20. A second surface contact layer E20b is formed on the second drain region DR21. The second drain electrode E21b is formed on the second surface contact layer E20b.

The first surface contact layer (E10), the second surface contact layer (E20b), the surface contact layers (E0, E0b), and the common surface contact layer E30 are made of a conductive material. Examples of such a conductive material include an impurity-doped polysilicon, a metal (aluminum, etc.), or a silicide (tungsten silicide, titanium silicide, cobalt silicide, nickel silicide, etc.).

The first gate electrode G11 is formed, via a left-side first gate insulating film G10, over a region between the left-side source region SR and the left-side first drain region DR11. The second gate electrode G21 is formed, via a left-side second gate insulating film G20, over a region between the left-side source region SR and the common drain region DR31.

The first gate electrode G11 is formed, via a right-side first gate insulating film G10, over a region between the right-side source region SR and the common drain region DR31. The second gate electrode G21 is formed, via a right-side second gate insulating film G20, over a region between the right-side source region SR and the right-side second drain region DR21.

A left-side first transistor Q11 includes the first drain region DR11 and the left-side source region SR. A left-side second transistor Q12 includes the common drain region DR31 and the left-side source region SR. That is, the left-side source region SR is common to the left-side first transistor Q11 and the second transistor Q12.

A right-side first transistor Q11b includes the common drain region DR31 and the right-side source region SR. A right-side second transistor Q12b includes the second drain region DR21 and the right-side source region SR. That is, the right-side source region SR is common to the right-side first transistor Q11b and the second transistor Q12b.

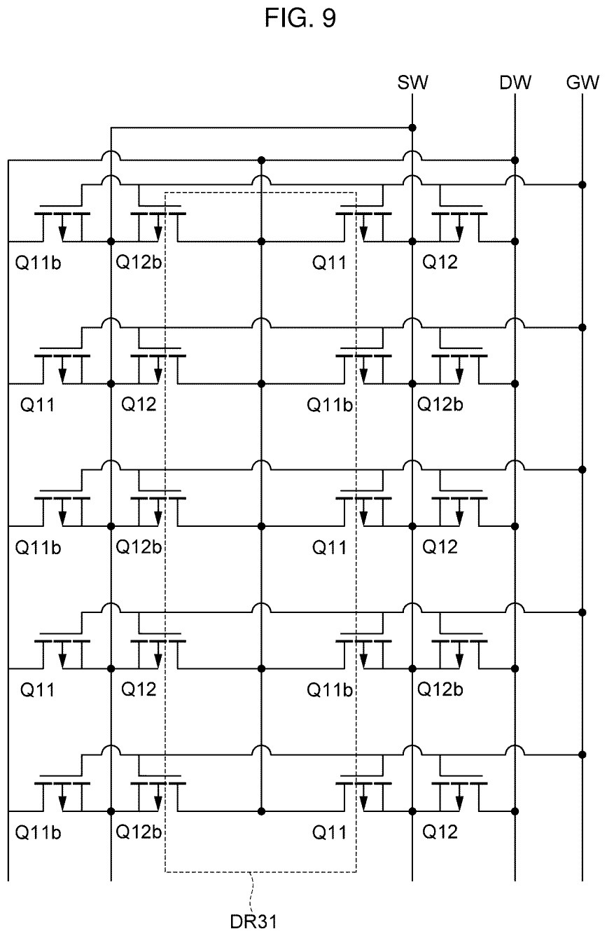

FIG. 9 is a circuit diagram of a transistor group connected in parallel.

Each field effect transistor shown in FIG. 5 is an NMOS (N-channel MOS) FET. The common drain region DR31 is common to the second transistors (Q12b, Q12) and the first transistors (Q11, Q11b), which are adjacent to each other.

The gate electrodes of the first transistors (Q11, Q11b) are electrically connected to the gate electrodes of the second transistors (Q12, Q12b), and are electrically connected to the gate electrode wiring line GW. The source electrodes of the first transistors (Q11, Q11b) are electrically connected to the source electrodes of the second transistors (Q12, Q12b), and are electrically connected to the source electrode wiring line SW. The drain electrodes of the first transistors (Q11, Q11b) are electrically connected to the drain electrodes of the second transistors (Q12, Q12b), and are electrically connected to the drain electrode wiring line DW. The transistor group is connected in parallel and can function as a high-withstand-voltage transistor.

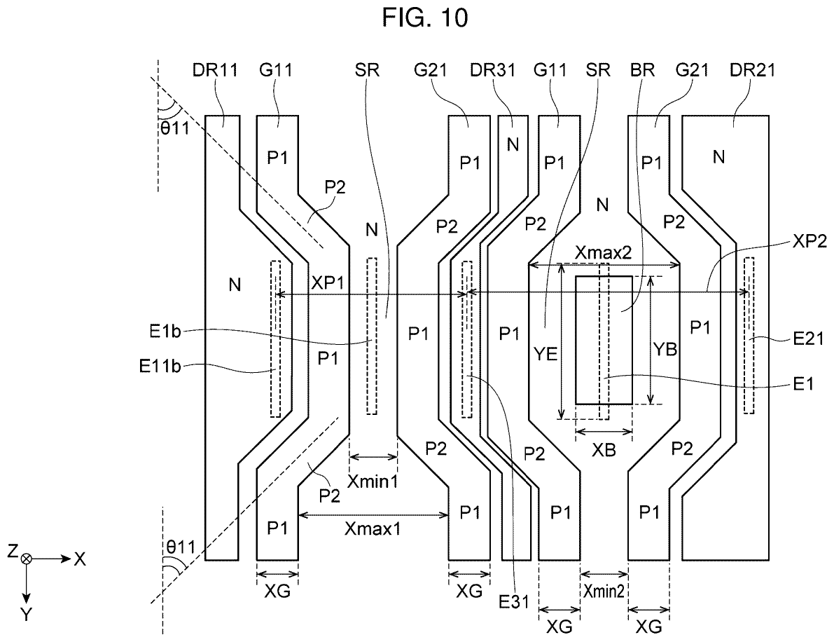

FIG. 10 is a plan view of a transistor.

FIG. 10 shows a structure in the vicinity of the transistor in an odd-numbered row shown in FIG. 6. The surface contact layer is not shown.

The first drain region DR11 and the first gate electrode G11 are adjacent to each other in the X axis direction in a plan view. The direction of each gate electrode is the direction of extension of the center position of the gate electrode in the width direction. The first gate electrode G11 has a first portion P1 extending in a direction parallel to the Y axis, and a second portion P2 extending in a direction at a first angle θ11 (acute angle) to the Y axis. Similarly, the second gate electrode G21 has a first portion P1 extending in a direction parallel to the Y axis, and a second portion P2 extending in a direction at a first angle θ11 (acute angle) to the Y axis. The first angle θ11 is an acute angle formed between the Y axis and the direction of extension of the second portion P2. The range of angles satisfies 30°≤θ11≤60°, for example. If the first angle θ11 were to fall below the lower limit of the range, the gap between conductive regions BR would tend to increase excessively, and if the first angle θ11 were to exceed the upper limit of the range, the configuration would be susceptible to the optical proximity effect, and thus, the above-mentioned range is preferable.

The left-side first gate electrode G11 extends such that the distance thereof to the source electrode E1b along the X axis direction is reduced with increased proximity in the Y axis direction thereof to the source electrode E1b. The left-side second gate electrode G21 extends such that the distance thereof to the source electrode E1b along the X axis direction is reduced with increased proximity in the Y axis direction thereof to the source electrode E1b.

The right-side first gate electrode G11 extends such that the distance thereof to the source electrode E1 along the X axis direction is increased with increased proximity thereof to the source electrode E1 in the Y axis direction. The right-side second gate electrode G21 extends such that the distance thereof to the source electrode E1 along the X axis direction is increased with increased proximity thereof to the source electrode E1 in the Y axis direction.

A Y axis direction dimension YE of the drain electrodes (E11b, E31, E21) and the source electrodes (E1b, E1) is greater than a Y axis direction dimension YB of the conductive region BR, and the dimension YE satisfies 1 μm≤YE≤4 μm, for example. This provides the effect of reducing contact resistance between the source region SR and the conductive region BR. The dimension YB satisfies 0.8 μm≤YB≤1.2 μm, for example. This provides the effect of mitigating rising potential in the source region SR. Rising potential refers to a case in which the actual potential increases to greater than the desired potential.

In the source region SR including the left-side source electrode E1b, a minimum distance Xmin1 in the X axis direction between the first gate electrode G11 and the second gate electrode G21 satisfies 0.4 μm≤Xmin1≤0.6μm, for example. A maximum distance Xmax1 in the X axis direction between the first gate electrode G11 and the second gate electrode G21 in the left-side source region SR satisfies Xmin1<Xmax1. Xmax1 satisfies 1 μm≤Xmax1≤1.5 μm, for example. This provides the effect of optimizing area efficiency. A ratio XR1=(Xmin1/Xmax1) between these dimensions satisfies 30%≤XR1≤50%, for example. In other words, the ratio of the minimum value to the maximum value of the distance in the X axis direction between the first gate electrode and the second gate electrode is 1% to 50%, inclusive. This provides the effect of optimizing the area ratio while mitigating a rise in electric potential in the source region SR. An optimal range for XR1 is 35%≤XR1≤45%, and a more optimal range is 38%≤XR1≤42%.

In the source region SR including the right-side source electrode E1, a maximum distance Xmax2 in the X axis direction between the first gate electrode G11 and the second gate electrode G21 satisfies 1 μm≤Xmax2≤1.5 μm, for example. A minimum distance Xmin2 in the X axis direction between the first gate electrode G11 and the second gate electrode G21 in the right-side source region SR satisfies Xmin2<Xmax2. Xmin2 satisfies 0.4 μm≤Xmin2≤0.6 μm, for example. A ratio XR2=(Xmin2/Xmax2) between these dimensions satisfies 1% ≤XR2≤50%, for example. For a similar reason to that of XR1, XR2 can be set to 30% ≤XR2≤50% as one example, preferably set to 35% ≤XR2≤45%, and more preferably set to 38%≤XR2≤42%.

The distance along the X axis direction between the first gate electrode G11 and the second gate electrode G21 periodically fluctuates along the Y axis direction, and the conductive region BR is disposed at a position in the source region SR with the maximum distance (Xmax2) along the X axis direction. The conductive region BR is not disposed at a position in the source region SR with the minimum distance (Xmin2) along the X axis direction.

The conductive region BR is disposed in a region with a wide gap between the two wave-shaped gate electrodes. In this structure, the effective width along which carriers travel is increased as compared to simply linear gate electrodes, and the effective gate width is increased by approximately 8% as compared to linear gate electrodes, for example. Thus, the ON-resistance per unit area can be reduced by 5-6%, for example, and the gate capacitance can be reduced by 20%, for example.

The plan view shape of the conductive region BR is rectangular, and the dimension XB in the X axis direction can be set less than the dimension Xmin1 (or Xmin2). This provides the effect of reducing the cell pitch. XB satisfies 0.2 μm≤XB≤0.5μm, for example. This provides the effect of reducing the cell pitch. The dimension YB in the Y axis direction of the conductive region BR can be set to less than the dimension YE in the Y axis direction of the source electrode E1 (YB<YE). YB satisfies 0.7 μm≤YB≤1.5 μm, for example. This provides the effect of optimizing the area ratio while mitigating a rise in electric potential in the source region SR.

Also, a differential dimension DIF=(Xmax2−XB) can be defined. DIF satisfies 0.6 μm≤DIF≤1.1 μm, for example. This provides the effect of optimizing area efficiency.

A gate electrode width XG in the X axis direction between the first gate electrode G11 and the second gate electrode G21 is 0.35 μm, for example. The gate electrode width XG satisfies 0.1 μm≤XG≤0.8 μm, for example.

An X axis direction width (cell pitch XP1) between the left-side first drain electrode E11b and the common drain electrode E31 is 1.74 μm, for example. An X axis direction width (cell pitch XP2) between the right-side second drain electrode E21 and the common drain electrode E31 is 2.54 μm, for example. The cell pitch in this example is set on the basis of the center position of each drain electrode in the X axis direction. The cell pitch XP1 satisfies 1.5 μm≤XP1≤2.0 μm, for example. This provides the effect of optimizing area efficiency. The cell pitch XP2 satisfies 2.0 μm≤XP2≤3.0 μm, for example. This provides the effect of optimizing area efficiency.

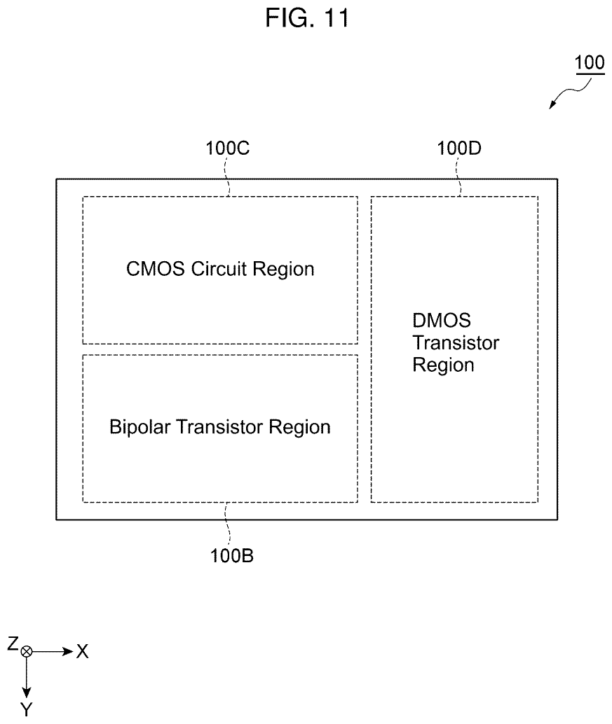

FIG. 11 is a plan view of a semiconductor chip including a BCD circuit.

The field effect transistor structure described above can also be applied to a field effect transistor in a bipolar-CMOS-DMOS (BCD) chip. The semiconductor chip 100 of this example includes a bipolar transistor region 100B, a CMOS circuit region 100C, and a DMOS transistor region 100D. The bipolar transistor region 100B includes one or more bipolar transistors, and is an analog block to which analog signals such as signals from various sensors are inputted.

The CMOS circuit region 100C includes a plurality of field effect transistors that constitute one or more complementary metal-oxide-semiconductor (CMOS) circuits, and is a digital block to which digital signals are inputted. The DMOS transistor region 100D includes one or more double-diffused metal-oxide-semiconductor (DMOS)-field effect transistors (FET), and is a power block that can process high voltage signals. In the BCD chip, sensor signals are inputted to the analog block, control signals are inputted to the digital block, and on the basis of the outputs thereof, the output signal of the power block can be controlled.

Each block includes one or more device regions. A plurality of device regions are set in the DMOS transistor region 100D, for example, and each device region includes the above-mentioned field effect transistor surrounded by an isolation structure. The semiconductor chip 100 of this example is a BCD chip, but the structures of the above embodiments can also be applied to semiconductor chips of types other than the BCD chip.

If an N-type well region is used in a bipolar transistor or CMOS circuit constituting the BCD chip, such regions can be formed in the same step as forming the N-type well region of the DMOS-FET.

Next, the materials and impurity concentrations of each of the above-mentioned semiconductor regions will be described.

The semiconductor material constituting the above-mentioned semiconductor chip 100 is silicon (Si). The semiconductor material constituting the semiconductor chip 100 can also be a compound semiconductor. Such compound semiconductors include III-V compound semiconductors, IV-IV compound semiconductors, or mixed crystal semiconductors including the foregoing semiconductors. Ga-containing semiconductors such as GaAs and GaN can be used as the III-V compound semiconductors. Si-containing semiconductors such as SiC and SiGe can be used as the IV-IV compound semiconductors. Impurities can be added to the semiconductor regions through ion implantation or through diffusion.

Specifically, the material of the semiconductor substrate 1A includes silicon (Si). The material of the semiconductor substrate 1A can also be made of a compound semiconductor such as silicon carbide (SiC) or gallium nitride (GaN), for example. The conductivity type of the semiconductor substrate 1A is the P type (first conductivity type), and the impurity concentration (CIA) can be set to 1×10¹⁴ cm⁻³ to 5×10¹⁸ cm⁻³, for example. The thickness of the semiconductor substrate 1A is 250 μm to 800 μm, for example.

The material of the first N-type well region 1B can be the same as the semiconductor material of the semiconductor substrate 1A. The conductivity type of the first N-type well region 1B is the N type (second conductivity type), and the impurity concentration (C_{1B}) can be set to 1×10¹⁶ cm⁻³ to 1×10¹⁸ cm⁻³, for example. The thickness of the first N-type well region 1B can be set to 0.5 μm to 4 μm, for example.

The material of the P-type well region 1C can be the same as the semiconductor material of the semiconductor substrate 1A. The conductivity type of the P-type well region 1C is the P type (first conductivity type), and the impurity concentration (C_{1C}) can be set to 1×10¹⁶ cm⁻³ to 1×10¹⁸ cm⁻³, for example. The thickness of the P-type well region 1C can be set to 0.5 μm to 4 μm, for example.

The material of the P-type semiconductor layer 1E can be the same as the semiconductor material of the semiconductor substrate 1A. The conductivity type of the P-type semiconductor layer 1E is the P type (first conductivity type), and the impurity concentration (CIE) can be set to 5×10¹⁶ cm⁻³ to 5×10¹⁸cm⁻³, and set higher than the impurity concentration of the P-type well region 1C, for example. The thickness of the P-type semiconductor layer 1E can be set to 0.3 μm to 1 μm, for example.

The material of the conductive region BR can be the same as the semiconductor material of the semiconductor substrate 1A. The conductivity type of the conductive region BR is the P type (first conductivity type), and the impurity concentration (CBR) can be set to 1×10¹⁹ cm⁻³ to 5×10²¹ cm⁻³, and set higher than the impurity concentration of the P-type well semiconductor layer 1E, for example. The thickness of the conductive region BR can be set to 0.2 μm to 1.0 μm, for example.

The material of the source region SR and the drain region (DR11, DR21) can be the same as the semiconductor material of the semiconductor substrate 1A. The conductivity type of the source region SR and the drain regions (DR11, DR21) is the N type (second conductivity type), and the respective impurity concentrations (CSR, CDR) can be set to 1×10¹⁹ cm⁻³ to 5×10²¹cm⁻³, for example. The thickness of the source region SR and the drain regions (DR11, DR21) can be set to 0.2 μm to 1 μm, for example, but a shallower or deeper structure can also be provided therefor.

The material of the lower drain regions (DR10, DR20) positioned below the drain regions (DR11, DR21) can be the same as the semiconductor material of the semiconductor substrate 1A. The conductivity type of the lower drain regions (DR10, DR20) is the N type (second conductivity type), and the impurity concentration (CUDR) is set lower than the impurity concentration (CDR) of the drain regions, and can be set to 1×10¹⁷ cm⁻³ to 1×10¹⁹ cm⁻³, for example. The thickness of the lower drain regions (DR10, DR20) can be set to greater than the drain regions (DR11, DR21).

In the example above, an NMOS-FET was described, but a similar method can be applied to a PMOS-FET by interchanging the first conductivity type and the second conductivity type, thereby attaining a similar effect.

Note: As described above, the various embodiments of this disclosure can be defined as follows.

[A1] A semiconductor device, including, in a plan view as seen from a Z axis direction, where an XYZ three-dimensional orthogonal coordinate system with the Z axis direction as a depth direction is set: a source region SR extending along a Y axis direction; a first drain region DR11 extending along the Y axis direction; a first gate electrode G11 disposed between the source region SR and the first drain region DR11; a second drain region DR21 positioned across the source region SR from the first drain region DR11, and extending along the Y axis direction; and a second gate electrode G21 disposed between the source region SR and the second drain region DR21, wherein the first gate electrode G11 extends in a meander along the Y axis direction, wherein the second gate electrode G21 extends in a meander along the Y axis direction, and wherein, in the source region SR disposed between the first gate electrode G11 and the second gate electrode G21, a conductive region BR having a conductivity type opposite to the source region SR is formed, and the source region SR and the conductive region BR are electrically connected to each other.

[A2] The semiconductor device according to [A1], wherein a distance along an X axis direction between the first gate electrode G11 and the second gate electrode G21 periodically fluctuates along the Y axis direction, and wherein the conductive region BR is disposed at a position in the source region SR with the distance along the X axis direction at a maximum value (Xmax2), and is not disposed at a position in the source region SR with the distance along the X axis direction at a minimum value (Xmin2).

[A3] The semiconductor device according to [A2], wherein a ratio of the minimum value (Xmin2) to the maximum value (Xmax2) of the distance along the X axis direction between the first gate electrode G11 and the second gate electrode G21 is 1% to 50%, inclusive.

[A4] The semiconductor device according to [A1], wherein the first gate electrode G11 and the second gate electrode G21 respectively have a first portion P1 extending in a direction parallel to the Y axis, and a second portion P2 extending in a direction at a first angle θ11 to the Y axis, the first angle θ11 being an acute angle and satisfying 30°≤θ11≤60°.

[A5] The semiconductor device according to [A1], further including: a semiconductor substrate 1A of a first conductivity type; a second conductivity type well region (1B) formed on the semiconductor substrate 1A; a first conductivity type well region (1D) formed in the second conductivity type well region; and a first conductivity type semiconductor layer (1E) disposed in the first conductivity type well region (1D), wherein the conductivity type of the conductive region BR is the first conductivity type, wherein the conductive region BR is connected to the semiconductor layer (1E), and wherein an impurity concentration of the conductive region BR is greater than an impurity concentration of the semiconductor layer (1E).

[A6] A semiconductor device, including, in a plan view as seen from a Z axis direction, where an XYZ three-dimensional orthogonal coordinate system with the Z axis direction as a depth direction is set: a first source region (left-side source region SR of FIG. 6) extending along a Y axis direction; a second source region (right-side source region SR of FIG. 6) extending along the Y axis direction; a first drain region (left-side first drain region DR11 of FIG. 6) extending along the Y axis direction; a second drain region (right-side second drain region DR21 of FIG. 6) extending along the Y axis direction; a common drain region (common drain region DR31 in center of FIG. 6) extending along the Y axis direction; a first-side first gate electrode (left-side first gate electrode G11 of FIG. 6) disposed between the first source region and the first drain region; a first-side second gate electrode (left-side second gate electrode G21 of FIG. 6) disposed between the first source region and the common drain region; a second-side first gate electrode (right-side first gate electrode G11 of FIG. 6) disposed between the second source region and the common drain region; and a second-side second gate electrode (right-side second gate electrode G21 of FIG. 6) disposed between the second source region and the second drain region, wherein, along an X axis direction, the first drain region DR11, the first-side first gate electrode (left-side first gate electrode G11 of FIG. 6), the first source region (left-side source region SR of FIG. 6), the first-side second gate electrode (left-side second gate electrode G21 of FIG. 6), the common drain region DR31, the second-side first gate electrode (right-side first gate electrode G11 of FIG. 6), the second source region (right-side source region SR of FIG. 6), the second-side second gate electrode (right-side second gate electrode G21 of FIG. 6), and the second drain region DR21 are disposed in sequence, wherein the first-side first gate electrode (left-side first gate electrode G11 of FIG. 6) extends in a meander along the Y axis direction, wherein the first-side second gate electrode (left-side second gate electrode G21 of FIG. 6) extends in a meander along the Y axis direction, wherein the second-side first gate electrode (right-side first gate electrode G11 of FIG. 6) extends in a meander along the Y axis direction, wherein the second-side second gate electrode (right-side second gate electrode G21 of FIG. 6) extends in a meander along the Y axis direction, wherein, in the first source region (left-side source region SR of FIG. 6) disposed between the first-side first gate electrode (left-side first gate electrode G11 of FIG. 6) and the first-side second gate electrode (left-side second gate electrode G21 of FIG. 6), a first conductive region (conductive region BR in left column of FIG. 6) having a conductivity type opposite to the first source region is formed, and the first source region and the first conductive region are electrically connected to each other, wherein, in the second source region (right-side source region SR of FIG. 6) disposed between the second-side first gate electrode (right-side first gate electrode G11 of FIG. 6) and the second-side second gate electrode (right-side second gate electrode G21 of FIG. 6), a second conductive region (conductive region BR in right column of FIG. 6) having a conductivity type opposite to the second source region is formed, and the second source region and the second conductive region are electrically connected to each other, and wherein a position in the Y axis direction providing a maximum value for a distance between the first-side first gate electrode (left-side first gate electrode G11 of FIG. 6) and the first-side second gate electrode (left-side second gate electrode G21 of FIG. 6) differs from a position in the Y axis direction providing a maximum value for the distance between the second-side first gate electrode (right-side first gate electrode G11 of FIG. 6) and the second-side second gate electrode (right-side second gate electrode G21 of FIG. 6).

In the above-mentioned semiconductor device, the gate electrodes are formed in a meander shape, and the conductive regions BR are provided, thereby allowing for a mitigation of a decrease in gate width and an increase in gate capacitance, reducing the ON-resistance, increasing the switching efficiency, and improving the characteristics of the field effect transistor. The semiconductor device (see FIG. 6) includes at least four columns of meandering gate electrodes, and the Y axis direction positions thereof providing the maximum width therebetween differ, thereby allowing for a reduced overall area.

[A7] The semiconductor device according to [A6], wherein a distance along the X axis direction between the first-side first gate electrode (G11) and the first-side second gate electrode (G21) periodically fluctuates along the Y axis direction, and wherein the first conductive region (BR) is disposed at a position in the first source region (SR) with the distance along the X axis direction at a maximum value (Xmax1), and is not disposed at a position in the first source region (SR) with the distance along the X axis direction at a minimum value (Xmin1).

The conductive region BR is disposed at a position allowing for the above-mentioned distance to be at the maximum value at a first side (left side), allowing for reduced area without a degradation in functionality overall.

[A8] The semiconductor device according to [A7], wherein a distance along the X axis direction between the second-side first gate electrode (G11) and the second-side second gate electrode (G21) periodically fluctuates along the Y axis direction, and wherein the second conductive region (BR) is disposed at a position in the second source region (SR) with the distance along the X axis direction at a maximum value (Xmax2), and is not disposed at a position in the second source region (SR) with the distance along the X axis direction at a minimum value (Xmin2).

The conductive region BR is disposed at a position allowing for the above-mentioned distance to be at the maximum value at a second side (right side), allowing for a reduced area without a degradation in functionality overall.

[A9] The semiconductor device according to [A6], wherein a ratio (XR1) of the minimum value to the maximum value of the distance along the X axis direction between the first-side first gate electrode (G11) and the first-side second gate electrode (G21) and a ratio (XR2) of the minimum value to the maximum value of the distance along the X axis direction of the second-side first gate electrode (G11) and the second-side second gate electrode (G21) are both 1% to 50%, inclusive.

[A9-1] The semiconductor device according to [A9], wherein the ratio (XR1, XR2) is 30% to 50%, inclusive.

[A9-2] The semiconductor device according to [A9], wherein the ratio (XR1, XR2) is 35% to 45%, inclusive.

[A9-3] The semiconductor device according to [A9], wherein the ratio (XR1, XR2) is 38% to 42%, inclusive.

[A10] The semiconductor device according to [A6], wherein the first-side first gate electrode, the first-side second gate electrode, the second-side first gate electrode, and the second-side second gate electrode respectively have a first portion extending in a direction parallel to the Y axis, and a second portion extending in a direction at a first angle θ11 to the Y axis, the first angle θ11 being an acute angle and satisfying 30°≤θ11≤60°.

Among the ranges of the various parameters described above, if the range of a given parameter P is given as Pₘᵢₙ≤P≤Pₘₐₓ, then the following ranges may be set: (Pₘᵢₙ+ΔP)≤P≤(Pₘₐₓ−ΔP), ΔP=(Pₘₐₓ−Pₘᵢₙ)×R %, R=10. Additionally, R may be set to 20, 30, or 40.

The various exemplary embodiments were described above, but the invention is not limited to the exemplary embodiments, and various omissions, substitutions, and modifications may be made. Also, it is possible to combine elements of various embodiments to form another embodiment. Additionally, the various embodiments of this disclosure were described in this specification for the purpose of explanation, and it should be understood that various modifications can be made without departing from the scope and spirit of this disclosure. Thus, the various embodiments disclosed in this specification do not signify limitations to the invention, and the true scope and spirit of the invention is indicated by the attached claims.

What is claimed is:

1. A semiconductor device, comprising, in a plan view as seen from a Z axis direction, where an XYZ three-dimensional orthogonal coordinate system with the Z axis direction as a depth direction is set:
a source region extending along a Y axis direction;
a first drain region extending along the Y axis direction;
a first gate electrode disposed between the source region and the first drain region;
a second drain region positioned across the source region from the first drain region, and extending along the Y axis direction; and
a second gate electrode disposed between the source region and the second drain region,
wherein the first gate electrode extends in a meander along the Y axis direction,
wherein the second gate electrode extends in a meander along the Y axis direction, and
wherein the source region is disposed between the first gate electrode and the second gate electrode, and in the source region, a conductive region having a conductivity type opposite to a conductivity type of the source region is formed, and the source region and the conductive region are electrically connected to each other.

2. The semiconductor device according to claim 1,
wherein a distance along an X axis direction between the first gate electrode and the second gate electrode periodically fluctuates along the Y axis direction, and
wherein the conductive region
is disposed at a position in the source region with the distance along the X axis direction at a maximum value, and
is not disposed at a position in the source region with the distance along the X axis direction at a minimum value.

3. The semiconductor device according to claim 2,
wherein a ratio of the minimum value to the maximum value of the distance along the X axis direction between the first gate electrode and the second gate electrode is 1% to 50%, inclusive.

4. The semiconductor device according to claim 1,
wherein the first gate electrode and the second gate electrode respectively have a first portion extending in a direction parallel to the Y axis, and a second portion extending in a direction at a first angle θ11 to the Y axis, the first angle θ11 being an acute angle and satisfying 30°≤θ11≤60°.

5. The semiconductor device according to claim 1, further comprising:
a semiconductor substrate of a first conductivity type;
a second conductivity type well region formed on the semiconductor substrate;
a first conductivity type well region formed in the second conductivity type well region; and
a first conductivity type semiconductor layer disposed in the first conductivity type well region,
wherein the conductivity type of the conductive region is the first conductivity type,
wherein the conductive region is connected to the semiconductor layer, and
wherein an impurity concentration of the conductive region is greater than an impurity concentration of the semiconductor layer.

6. A semiconductor device, comprising, in a plan view as seen from a Z axis direction, where an XYZ three-dimensional orthogonal coordinate system with the Z axis direction as a depth direction is set:
a first source region extending along a Y axis direction;
a second source region extending along the Y axis direction;
a first drain region extending along the Y axis direction;
a second drain region extending along the Y axis direction;
a common drain region extending along the Y axis direction;
a first-side first gate electrode disposed between the first source region and the first drain region;
a first-side second gate electrode disposed between the first source region and the common drain region;
a second-side first gate electrode disposed between the second source region and the common drain region; and
a second-side second gate electrode disposed between the second source region and the second drain region,
wherein, along an X axis direction, the first drain region, the first-side first gate electrode, the first source region, the first-side second gate electrode, the common drain region, the second-side first gate electrode, the second source region, the second-side second gate electrode, and the second drain region are disposed in sequence,
wherein the first-side first gate electrode extends in a meander along the Y axis direction,
wherein the first-side second gate electrode extends in a meander along the Y axis direction,
wherein the second-side first gate electrode extends in a meander along the Y axis direction,
wherein the second-side second gate electrode extends in a meander along the Y axis direction,
wherein the first source region is disposed between the first-side first gate electrode and the first-side second gate electrode, and in the first source region, a first conductive region having a conductivity type opposite to a conductivity type of the first source region is formed, and the first source region and the first conductive region are electrically connected to each other,
wherein the second source region is disposed between the second-side first gate electrode and the second-side second gate electrode, and in the second source region, a second conductive region having a conductivity type opposite to a conductivity type of the second source region is formed, and the second source region and the second conductive region are electrically connected to each other, and
wherein a position in the Y axis direction providing a maximum value for a distance along the X axis direction between the first-side first gate electrode and the first-side second gate electrode differs from a position in the Y axis direction providing a maximum value for a distance along the X axis direction between the second-side first gate electrode and the second-side second gate electrode.

7. The semiconductor device according to claim 6,
wherein the distance along the X axis direction between the first-side first gate electrode and the first-side second gate electrode periodically fluctuates along the Y axis direction, and
wherein the first conductive region
is disposed at a position in the first source region with the distance between the first-side first gate electrode and the first-side second gate electrode along the X axis direction at the maximum value, and
is not disposed at a position in the first source region with the distance between the first-side first gate electrode and the first-side second gate electrode along the X axis direction at a minimum value.

8. The semiconductor device according to claim 7,
wherein the distance along the X axis direction between the second-side first gate electrode and the second-side second gate electrode periodically fluctuates along the Y axis direction, and
wherein the second conductive region
is disposed at a position in the second source region with the distance along the X axis direction between the second-side first gate electrode and the second-side second gate electrode at the maximum value, and
is not disposed at a position in the second source region with the distance along the X axis direction between the second-side first gate electrode and the second-side second gate electrode at a minimum value.

9. The semiconductor device according to claim 6,
wherein a ratio of a minimum value to the maximum value of the distance along the X axis direction between the first-side first gate electrode and the first-side second gate electrode and a ratio of a minimum value to the maximum value of the distance along the X axis direction between the second-side first gate electrode and the second-side second gate electrode are both 1% to 50%, inclusive.

10. The semiconductor device according to claim 6,
wherein the first-side first gate electrode, the first-side second gate electrode, the second-side first gate electrode, and the second-side second gate electrode respectively have a first portion extending in a direction parallel to the Y axis, and a second portion extending in a direction at a first angle θ11 to the Y axis, the first angle θ11 being an acute angle and satisfying 30°≤θ11≤60°.
